(19) United States
(12) Patent Application Publication
(10) Pub. No.: US 2025/0329571 A1
(43) Pub. Date: Oct. 23, 2025

(54) SAMPLE HOLDER

(71) Applicant: KYOCERA Corporation, Kyoto-shi, Kyoto (JP)

(72) Inventor: Satoru KAMITANI, Kirishima-shi (JP)

(73) Assignee: KYOCERA Corporation, Kyoto-shi, Kyoto (JP)

(21) Appl. No.: 18/850,875

(22) PCT Filed: Mar. 22, 2023
(86) PCT No.: PCT/JP2023/011273

§ 371 Date: Sep. 25, 2024

(30) Foreign Application Priority Data
Mar. 29, 2022 (JP) 2022-054481

(51) Int. Cl. H01L 21/687

(52) U.S. Cl. CPC H01L 21/68785; H01L 21/68757

(57) ABSTRACT

A sample holder according to the present disclosure includes a ceramic substrate, a base plate, and a tubular member. The ceramic substrate includes a first surface being a sample holding surface and a second surface located opposite to the first surface. The base plate includes a third surface located on the second surface of the ceramic substrate and facing the second surface, a fourth surface located opposite to the third surface, and a through hole passing through the third surface and the fourth surface. The tubular member is located in the through hole and bonded to the second surface. The sample holder according to the present disclosure includes a sealing member between an inner peripheral surface of the through hole and an outer peripheral surface of the tubular member.

### CROSS REFERENCE TO RELATED APPLICATIONS

This application is a national stage application of International Application No. PCT/JP2023/011273, filed on Mar. 22, 2023, which designates the United States, incorporated herein by reference, and which claims the benefit of priority from Japanese Patent Application No. 2022-054481, filed on Mar. 29, 2022, the entire contents of which are incorporated herein by reference.

### TECHNICAL FIELD

An embodiment of the disclosure relates to a sample holder.

### BACKGROUND OF INVENTION

Conventionally, as a sample holder used in a semiconductor integrated circuit manufacturing device or the like, a sample holder is known in which a ceramic substrate and a base plate provided under the ceramic substrate are bonded to each other with an adhesive. A through hole reaching the lower surface of the ceramic substrate is formed in the base plate. For example, a terminal connected to an internal electrode of the ceramic substrate is inserted into the through hole (see Patent Document 1).

### CITATION LIST

### Patent Literature

Patent Document 1: JP 2000-44345 A

### SUMMARY

In an aspect of an embodiment, a sample holder includes a ceramic substrate, a base plate, and a tubular member. The ceramic substrate includes a first surface being a sample holding surface and a second surface located opposite to the first surface. The base plate includes a third surface located on the second surface of the ceramic substrate and facing the second surface, a fourth surface located opposite to the third surface, and a through hole passing through the third surface and the fourth surface. The tubular member is located in the through hole and bonded to the second surface. In an aspect of the embodiment, the sample holder includes a sealing member between an inner peripheral surface of the through hole and an outer peripheral surface of the tubular member.

### BRIEF DESCRIPTION OF THE DRAWINGS

FIG. 1 is a schematic cross-sectional view illustrating a configuration example of a semiconductor manufacturing device using a sample holder according to a first embodiment.

FIG. 2 is a schematic cross-sectional view illustrating a configuration example of the sample holder according to the first embodiment.

FIG. 3 is a schematic cross-sectional view illustrating a configuration example of a sample holder according to a second embodiment.

FIG. 4 is a schematic enlarged view of one end portion of a tubular member.

FIG. 5 is a schematic cross-sectional view illustrating a configuration example of a sample holder according to a third embodiment.

FIG. 6 is a schematic cross-sectional view illustrating a configuration example of a groove portion.

FIG. 7 is a schematic cross-sectional view illustrating a configuration example of the groove portion.

FIG. 8 is a schematic cross-sectional view illustrating a configuration example of the groove portion.

FIG. 9 is a schematic cross-sectional view illustrating a configuration example of the groove portion.

FIG. 10 is a schematic cross-sectional view illustrating a configuration example of a sample holder according to a fourth embodiment.

FIG. 11 is a schematic cross-sectional view illustrating a configuration example of a sample holder according to a fifth embodiment.

FIG. 12 is a schematic cross-sectional view illustrating a configuration example of a sample holder according to a sixth embodiment.

FIG. 13 is a schematic cross-sectional view illustrating a configuration example of a sample holder according to a seventh embodiment.

FIG. 14 is a schematic cross-sectional view illustrating a configuration example of a sample holder according to an eighth embodiment.

FIG. 15 is a schematic cross-sectional view illustrating a configuration example of the sample holder according to the eighth embodiment.

FIG. 16 is a schematic cross-sectional view illustrating a configuration example of a sample holder according to a ninth embodiment.

FIG. 17 is a schematic cross-sectional view illustrating a configuration example of a sample holder according to a tenth embodiment.

FIG. 18 is a schematic cross-sectional view illustrating a configuration example of a sample holder according to an eleventh embodiment.

FIG. 19 is a schematic cross-sectional view illustrating a configuration example of a sample holder according to a twelfth embodiment.

### DESCRIPTION OF EMBODIMENTS

Embodiments of a sample holder disclosed by the present application will be described in detail below with reference to the accompanying drawings. Note that the invention according to the present application is not limited by embodiments described below.

Although an example in which the sample holder according to the present disclosure is used in a semiconductor manufacturing device that processes a semiconductor wafer will be described below, the sample holder according to the present disclosure may be used to hold a sample other than a semiconductor wafer.

In recent years, the temperature of the environment in which the sample holder is used has increased, and a sample holder that can withstand use at higher temperatures is demanded. The adhesive for bonding the ceramic substrate and the base plate has a relatively low heat-resistant temperature, and thus using the adhesive under a high-temperature environment is difficult. It is conceivable that the ceramic substrate and the base plate are mechanically bonded instead of bonding with the adhesive.

However, when the ceramic substrate and the base plate are mechanically bonded to each other, ensuring the sealing property between the ceramic substrate and the base plate is difficult. Therefore, for example, when the sample holder is used in a vacuum environment, vacuum leakage may occur in the gap between the ceramic substrate and the base plate.

Providing a sample holder capable of easily ensuring the sealing property under a high-temperature environment is expected.

### First Embodiment

### Configuration of Semiconductor Manufacturing Device

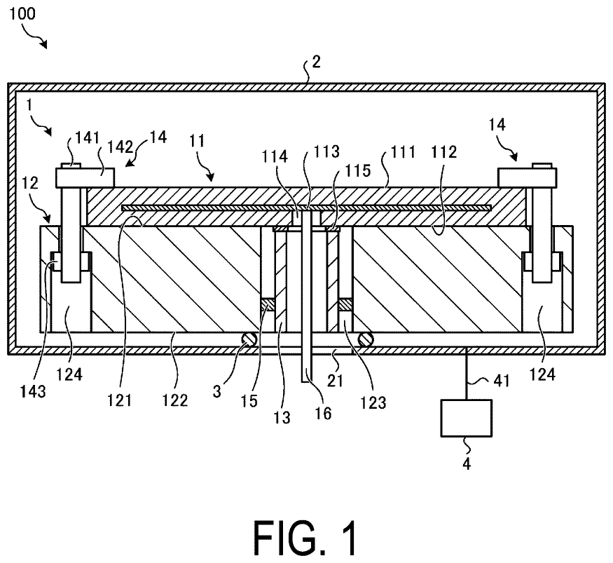

FIG. 1 is a schematic cross-sectional view illustrating a configuration example of a semiconductor manufacturing device using a sample holder according to a first embodiment.

Note that, in FIG. 1, among the components included in the semiconductor manufacturing device, components mainly necessary for describing the sample holder are illustrated, and other components are appropriately omitted. For example, the semiconductor manufacturing device may be a plasma treatment device that treats a semiconductor wafer using plasma. In this case, the semiconductor manufacturing device may include a shower head functioning as an electrode for plasma generation.

As illustrated in FIG. 1, a semiconductor manufacturing device 100 according to the first embodiment includes a sample holder 1, a treatment container 2, a first sealing member 3, and an exhaust mechanism 4.

A sample (here, a semiconductor wafer) to be treated is placed on the sample holder 1. The specific configuration of the sample holder 1 will be described later.

The treatment container 2 accommodates the sample holder 1. An opening 21 is located on the bottom portion of the treatment container 2. A terminal 16 described later is inserted into the opening 21. In other words, the terminal 16 is drawn to the outside of the treatment container 2 through the opening 21.

The first sealing member 3 is, for example, an O-ring made of rubber. The first sealing member 3 is located to surround the opening 21 of the treatment container 2. The first sealing member 3 is located between the lower surface of the sample holder 1 and the bottom surface of the treatment container 2, and is crushed by the sample holder 1 from above to seal the gap between the sample holder 1 and the treatment container 2. This seals the inside of the treatment container 2.

The exhaust mechanism 4 is connected to an exhaust port (not illustrated) of the treatment container 2 via an exhaust pipe 41. The exhaust mechanism 4 includes a vacuum pump, a pressure control valve, and the like, and exhausts the inside of the treatment container 2 through the exhaust pipe 41. This depressurizes the inside of the treatment container 2.

### Configuration of Sample Holder

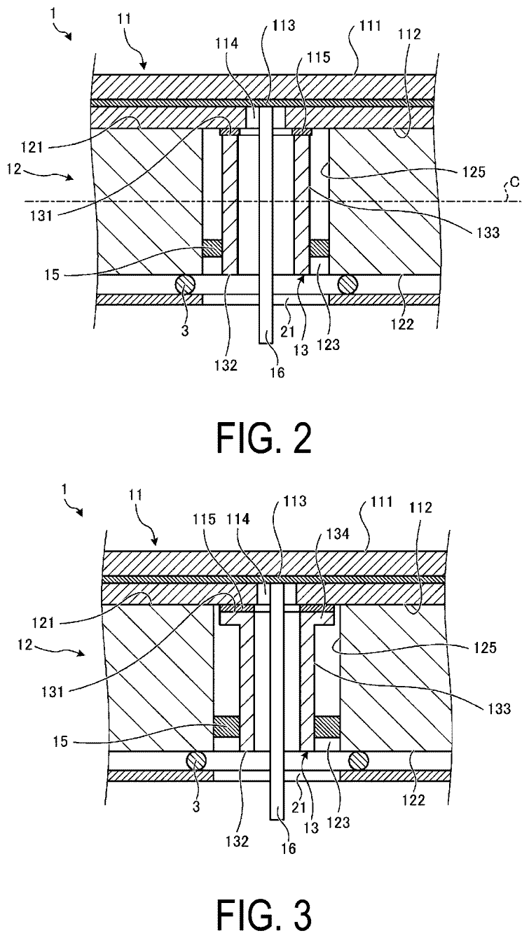

The configuration of the sample holder 1 will be further described with reference to FIG. 2. FIG. 2 is a schematic cross-sectional view illustrating a configuration example of the sample holder 1 according to the first embodiment.

As illustrated in FIGS. 1 and 2, the sample holder 1 includes a ceramic substrate 11, a base plate 12, a tubular member 13, a plurality of fixing portions 14, a second sealing member 15, and a terminal 16.

The ceramic substrate 11 has, for example, a disk shape. A first surface 111 which is one main surface (here, an upper surface) of the ceramic substrate 11 is a surface for holding a semiconductor wafer.

The ceramic substrate 11 may contain, for example, aluminum oxide (Al₂O₃), aluminum nitride (AlN), yttria (Y₂O₃), cordierite, silicon carbide (SiC), silicon nitride (Si₃N₄), or the like as a main component. The ceramic substrate 11 is obtained by, for example, laminating and firing a plurality of green sheets.

A heat generating resistor 113 is located inside the ceramic substrate 11. The heat generating resistor 113 is a member that generates heat when electrical current flows therethrough. The heat generating resistor 113 is provided to heat the semiconductor wafer held on the first surface 111. The heat generating resistor 113 may have a linear pattern (meander pattern) having a plurality of folded portions.

The heat generating resistor 113 includes, for example, a metal material. Examples of the metal material constituting the heat generating resistor 113 include tungsten, molybdenum, rhenium, an alloy thereof, and platinum. The heat generating resistor 113 may contain a glass component, for example, an oxide such as silicon dioxide.

Note that a conductive member other than the heat generating resistor 113 may be located inside the ceramic substrate 11. For example, an electrode for electrostatic adsorption or a high-frequency electrode to which high-frequency power for plasma generation is applied may be located inside the ceramic substrate 11. Examples of the metal material constituting the electrode for electrostatic adsorption and the high-frequency electrode include tungsten, molybdenum, rhenium, an alloy thereof, and platinum.

A recessed portion 114 reaching the heat generating resistor 113 is located on a second surface 112 (here, a lower surface) of the ceramic substrate 11 opposite to the first surface 111.

The base plate 12 has, for example, a disk shape having a diameter larger than that of the ceramic substrate 11. The base plate 12 is located on the second surface 112 of the ceramic substrate 11. Specifically, the base plate 12 has a third surface 121 (here, an upper surface) facing the second surface 112 and a fourth surface 122 (here, a lower surface) opposite to the third surface 121.

The base plate 12 includes a through hole 123 passing through the third surface 121 and the fourth surface 122. The heat generating resistor 113 built in the ceramic substrate 11 is exposed to the outside via the opening 21 of the treatment container 2, the through hole 123 of the base plate 12, and the recessed portion 114 of the ceramic substrate 11.

The base plate 12 may be made of, for example, a metal. As a metal material forming the base plate 12, for example, aluminum matrix composite materials such as aluminum, stainless steel, titanium, and AlSiC can be used. The metal base plate 12 functions as a cooling member for cooling the ceramic substrate 11 heated by the heat generating resistor 113. The base plate 12 as the cooling member may have an internal flow path through which a cooling medium such as cooling water or cooling gas flows. The metal base plate 12 may be used as a high-frequency electrode to which high-frequency power for plasma generation is applied.

The tubular member 13 has a cylindrical shape, for example. The tubular member 13 is inserted into the through hole 123 of the base plate 12. In other words, the tubular member 13 is located in the through hole 123. A fifth surface 131 which is one surface (here, an upper end surface) of both end surfaces of the tubular member 13 is bonded to the second surface 112 of the ceramic substrate 11 via a bonding member 115. The bonding member 115 is, for example, a glass, a brazing material, or the like.

An outer diameter of the tubular member 13 is smaller than an inner diameter of the through hole 123 of the treatment container 2. That is, an inner peripheral surface 125 of the through hole 123 and an outer peripheral surface 133 of the tubular member 13 are separated from each other, and a gap (space) is located between the outer peripheral surface 133 of the tubular member 13 and the inner peripheral surface 125 of the through hole 123.

Note that a sixth surface 132, which is the other surface (here, a lower end surface) of both end surfaces of the tubular member 13, may protrude from the opening 21 of the treatment container 2 to the outside of the treatment container 2.

The terminal 16 is inserted into the tubular member 13. The terminal 16 is connected to the heat generating resistor 113 via the tubular member 13 and the recessed portion 114 of the ceramic substrate 11.

The fixing portion 14 mechanically joins the ceramic substrate 11 and the base plate 12 by clamping the ceramic substrate 11 and the base plate 12.

As an example, the fixing portion 14 includes a support member 141, a claw member 142, and a fastening member 143. The support member 141 is a member extending in the vertical direction. The support member 141 is inserted into an insertion hole 124 provided in the base plate 12, and extends above the base plate 12 via the insertion hole 124. The claw member 142 extends horizontally from the distal end portion of the support member 141 and is in contact with the outer peripheral portion of the first surface 111 of the ceramic substrate 11. The fastening member 143 is, for example, a nut. The fastening member 143 is provided at the base end portion of the support member 141 and in contact with a step provided inside the insertion hole 124. The fixing portion 14 moves the support member 141 and the claw member 142 downward by fastening the fastening member 143 to the support member 141. Thus, the ceramic substrate 11 and the base plate 12 are pressed against each other, whereby the ceramic substrate 11 and the base plate 12 are bonded to each other.

Note that the configuration of the fixing portion 14 illustrated in FIG. 1 is an example, and any configuration may be used as long as the ceramic substrate 11 and the base plate 12 are mechanically bonded to each other.

When the ceramic substrate 11 and the base plate 12 are mechanically bonded to each other, the ceramic substrate 11 and the base plate 12 do not need to be bonded to each other with an adhesive. Therefore, the sample holder 1 can be easily used under a high-temperature environment. On the other hand, when the ceramic substrate 11 and the base plate 12 are mechanically bonded to each other, ensuring the sealing property between the ceramic substrate 11 and the base plate 12 is difficult as compared with the case where the ceramic substrate 11 and the base plate 12 are bonded to each other with an adhesive. Therefore, vacuum leakage may occur in the gap between the ceramic substrate 11 and the base plate 12, and maintaining the decompressed state of the treatment container 2 is difficult.

Therefore, in the sample holder 1 according to the embodiment, the gap between the inner peripheral surface 125 of the through hole 123 and the outer peripheral surface 133 of the tubular member 13 is sealed by the second sealing member 15.

The second sealing member 15 is, for example, a rubber-like member such as silicone resin. The second sealing member 15 is located between the inner peripheral surface 125 of the through hole 123 and the outer peripheral surface 133 of the tubular member 13, and seals the gap between the through hole 123 and the tubular member 13.

As described above, by sealing the gap between the inner peripheral surface 125 of the through hole 123 and the outer peripheral surface 133 of the tubular member 13 communicating with the gap between the ceramic substrate 11 and the base plate 12 with the second sealing member 15, the occurrence of vacuum leakage can be reduced even when the sealing property between the ceramic substrate 11 and the base plate 12 is not sufficiently ensured. The gap between the inner peripheral surface 125 of the through hole 123 and the outer peripheral surface 133 of the tubular member 13, in which the second sealing member 15 is located, is more distant from the ceramic substrate 11, which is a heat generation source, than the gap between the ceramic substrate 11 and the base plate 12, and thus is less likely to be affected by heat from the ceramic substrate 11. Therefore, according to the sample holder 1 of the embodiment, ensuring the sealing property under a high-temperature environment is easy.

The second sealing member 15 is located on the fourth surface 122 side of the base plate 12 with respect to a center C of the base plate 12 in the thickness direction. In other words, the second sealing member 15 is located between the center C of the base plate 12 in the thickness direction and the fourth surface 122 of the base plate 12. Such a configuration can further reduce the influence of the heat from the ceramic substrate 11.

The space between the inner peripheral surface 125 of the through hole 123 and the outer peripheral surface 133 of the tubular member 13 on the third surface 121 side with respect to the center C of the base plate 12 in the thickness direction functions as a heat insulating layer, and thus the influence of heat on the second sealing member 15 can be further reduced.

Note that at least a portion of the second sealing member 15 may be located between the center C of the base plate 12 in the thickness direction and the fourth surface 122 of the base plate 12. That is, a portion of the second sealing member 15 may protrude from the fourth surface 122 of the base plate 12, or may be located between the center C of the base plate 12 in the thickness direction and the third surface 121 of the base plate 12. The second sealing member 15 may be provided to be flush with the fourth surface 122 of the base plate 12.

The thermal expansion coefficient of the tubular member 13 may be smaller than the thermal expansion coefficient of the ceramic substrate 11. By using the tubular member 13 having a relatively small thermal expansion coefficient, thermal expansion and contraction of the tubular member 13 in the longitudinal direction (the thickness direction of the ceramic substrate 11 and the base plate 12) can be reduced. This can reduce the stress applied to the bonding surface between the tubular member 13 and the second sealing member 15. Thus, the reliability under a high-temperature environment can be further enhanced.

Note that mullite, for example, can be used as the material of the tubular member 13 having a thermal expansion coefficient smaller than the thermal expansion coefficient of the ceramic substrate 11.

### Second Embodiment

FIG. 3 is a schematic cross-sectional view illustrating a configuration example of the sample holder 1 according to the second embodiment. As illustrated in FIG. 3, a surface area of the fifth surface 131, which is a bonding surface to the second surface 112 of the ceramic substrate 11, may be larger than a surface area of the sixth surface 132 located opposite to the fifth surface 131. For example, in the tubular member 13, one end portion 134 located on the ceramic substrate 11 side of both end portions in the longitudinal direction may have a flange shape. In this case, the fifth surface 131 which is the upper surface of the one end portion 134 has a larger surface area than the sixth surface 132 which is the lower surface of the other end portion.

With such a configuration, the bonding surface area between the ceramic substrate 11 and the tubular member 13 is increased. This can suitably reduce the occurrence of vacuum leakage from the gap between the ceramic substrate 11 and the tubular member 13. An increase in heat capacity of the tubular member 13 can be reduced by thickening only the one end portion 134 instead of thickening the tubular member 13 as a whole. This can reduce the influence of heat on the second sealing member 15 due to heat conduction from the ceramic substrate 11.

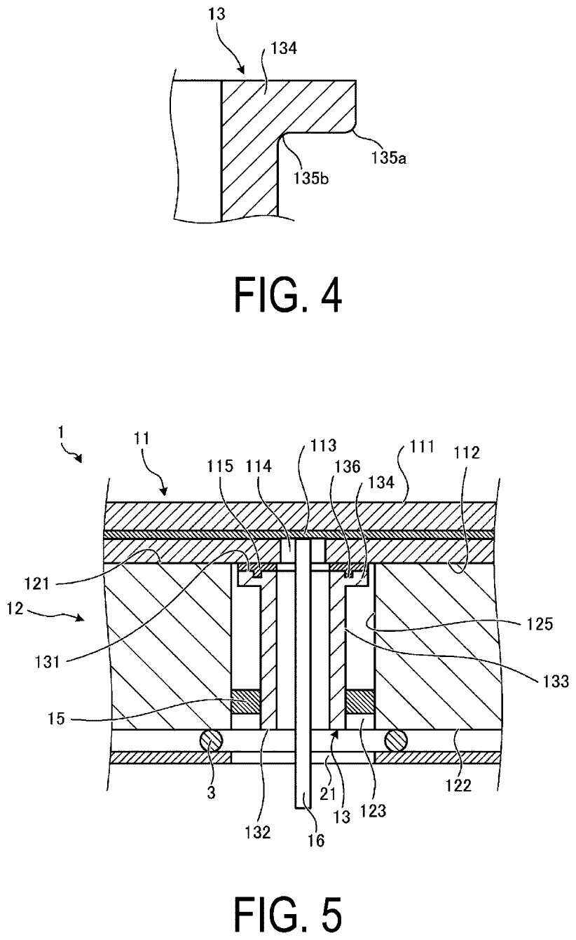

FIG. 4 is a schematic enlarged view of the one end portion 134 of the tubular member 13. As illustrated in FIG. 4, the one end portion 134 of the tubular member 13 may have a corner portion 135a curved in an R shape. The one end portion 134 of the tubular member 13 may have a nook portion 135b curved in an R shape.

This configuration can reduce concentration of thermal stress due to temperature cycles on the corner portion 135a and the nook portion 135b of the one end portion 134. Thus, occurrence of cracks in the tubular member 13 can be reduced.

Note that although FIG. 4 illustrates an example in which both the corner portion 135a and the nook portion 135b are curved, at least one of the corner portion 135a or the nook portion 135b of the one end portion 134 of the tubular member 13 may be curved.

### Third Embodiment

FIG. 5 is a schematic cross-sectional view illustrating a configuration example of the sample holder 1 according to the third embodiment. As illustrated in FIG. 5, in the sample holder 1 according to the third embodiment, the tubular member 13 may have a groove portion 136 in the fifth surface 131 which is the upper surface of the flange-shaped one end portion 134.

Since the groove portion 136 is located in the fifth surface 131, a contact surface area between the fifth surface 131 and the bonding member 115 is increased. Thus, the ceramic substrate 11 and the tubular member 13 can be more firmly bonded to each other.

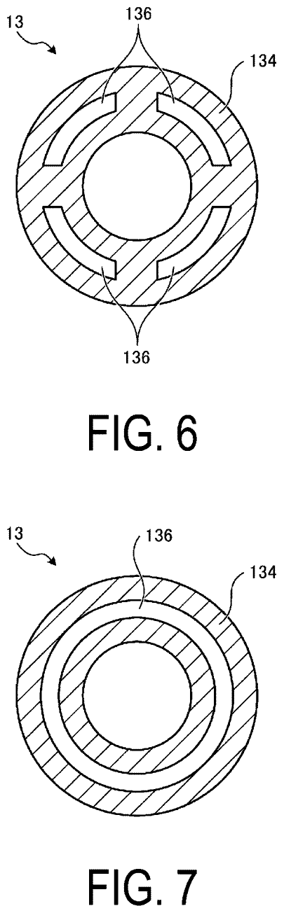

FIGS. 6 to 9 are schematic cross-sectional views illustrating configuration examples of the groove portion 136. Specifically, FIGS. 6 to 9 illustrate plan cross-sectional views when the one end portion 134 of the tubular member 13 is cut at a position above the bottom surface of the groove portion 136 and below the fifth surface 131 of the tubular member 13.

As illustrated in FIGS. 6 and 7, the tubular member 13 may include the groove portion 136 extending in the circumferential direction. FIG. 6 illustrates an example in which the tubular member 13 includes a plurality of groove portions 136 arranged in the circumferential direction. FIG. 7 illustrates an example in which the tubular member 13 includes the annular groove 136.

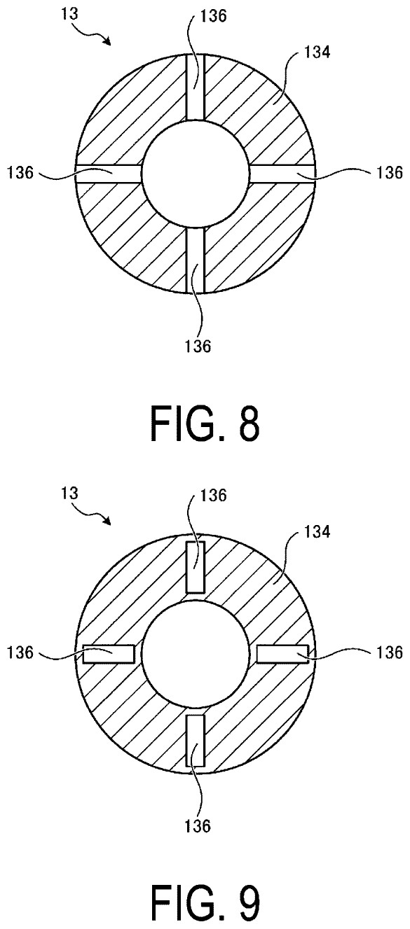

As illustrated in FIGS. 8 and 9, the tubular member 13 may include the groove portion 136 extending in the radial direction. FIG. 8 illustrates an example in which the tubular member 13 includes the groove portions 136 extending over the inner peripheral edge and the outer peripheral edge of the tubular member 13. FIG. 9 illustrates an example in which the tubular member 13 includes the groove portions 136 whose one end portion and the other end portion do not reach the inner peripheral edge and the outer peripheral edge of the tubular member 13, respectively.

### Fourth Embodiment

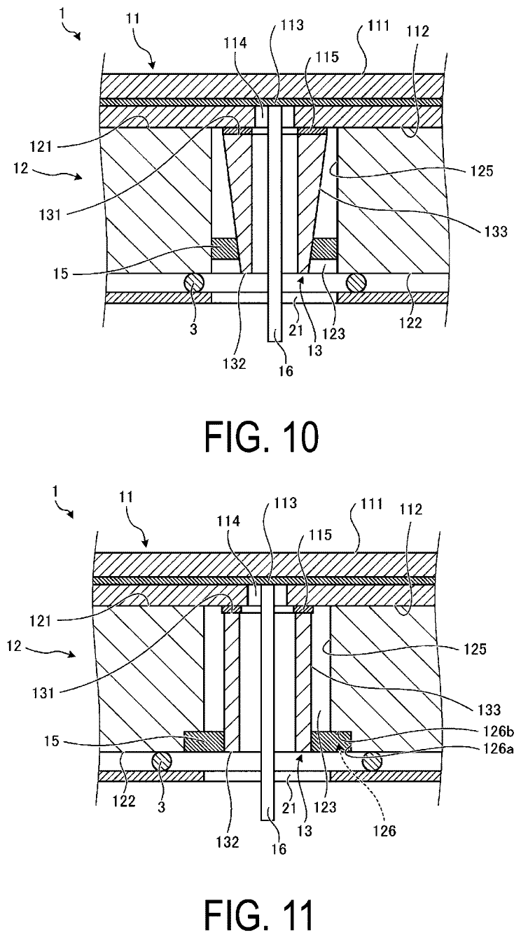

FIG. 10 is a schematic cross-sectional view illustrating a configuration example of the sample holder 1 according to the fourth embodiment. The shape of the tubular member 13 in which the surface area of the fifth surface 131 is larger than the surface area of the sixth surface 132 is not limited to the shape illustrated in FIG. 3.

For example, as illustrated in FIG. 10, the tubular member 13 may have a tapered shape that gradually narrows from the fifth surface 131 toward the sixth surface 132. Also in this configuration, the bonding surface area between the ceramic substrate 11 and the tubular member 13 is increased. This can suitably reduce the occurrence of vacuum leakage from the gap between the ceramic substrate 11 and the tubular member 13. By forming the tubular member 13 in a tapered shape, an increase in heat capacity of the tubular member 13 can be reduced as compared with a case where the tubular member 13 is uniformly thickened. This can reduce the influence of heat on the second sealing member 15 due to heat conduction from the ceramic substrate 11.

### Fifth Embodiment

FIG. 11 is a schematic cross-sectional view illustrating a configuration example of the sample holder 1 according to the fifth embodiment. As illustrated in FIG. 11, the base plate 12 may include a counterbore portion 126 recessed in the thickness direction of the base plate 12 at the opening portion of the fourth surface 122 in the through hole 123.

The counterbore portion 126 has a larger diameter than the through hole 123 of the base plate 12. Specifically, the counterbore portion 126 includes a side surface 126a located at a position farther away from the outer peripheral surface 133 of the tubular member 13 than the inner peripheral surface 125 of the through hole 123 in the radial direction of the tubular member 13. The counterbore portion 126 includes a stepped surface 126b between the side surface 126a and the inner peripheral surface 125 of the through hole 123. The second sealing member 15 according to the fifth embodiment is located in the counterbore portion 126.

With such a configuration, the position, thickness, and the like of the second sealing member 15 can be easily controlled. This can reduce, for example, the possibility that the second sealing member 15 comes too close to the ceramic substrate 11 or the thickness of the second sealing member 15 becomes insufficient. Since the base plate 12 is located between the second sealing member 15 and the ceramic substrate 11, radiant heat transmitted from the ceramic substrate 11 to the second sealing member 15 can be reduced by the base plate 12. Thus, the reliability of use under a high-temperature environment can be further enhanced.

### Sixth Embodiment

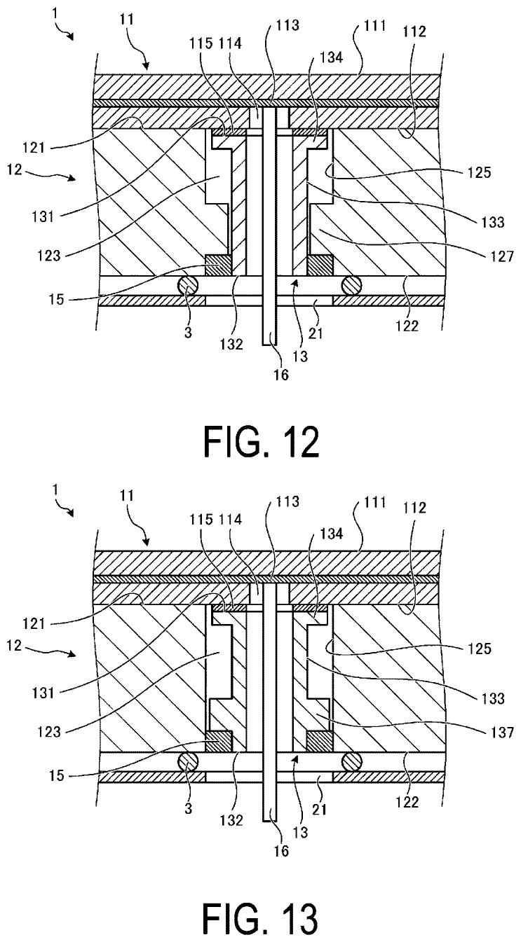

FIG. 12 is a schematic cross-sectional view illustrating a configuration example of the sample holder 1 according to the sixth embodiment. As illustrated in FIG. 12, the base plate 12 may include a protruding portion 127 (corresponding to an example of a first protruding portion) that protrudes from the inner peripheral surface 125 of the through hole 123 toward the inside of the through hole 123, that is, toward the outer peripheral surface 133 of the tubular member 13, in a middle portion of the through hole 123. The inner peripheral surface of the protruding portion 127 has a smaller diameter than the inner peripheral surface 125 of the through hole 123 and a larger diameter than the outer peripheral surface 133 of the tubular member 13.

In such a configuration, the lower side of the protruding portion 127 performs a function the same as or similar to that of the above-described counterbore portion 126 (see FIG. 11). That is, since the second sealing member 15 is located below the protruding portion 127, the position, the thickness, and the like of the second sealing member 15 can be easily controlled. Since the protruding portion 127 is located between the second sealing member 15 and the ceramic substrate 11, the radiant heat transmitted from the ceramic substrate 11 to the second sealing member 15 can be reduced by the protruding portion 127.

The base plate 12 including the protruding portion 127 can secure a large heat insulating space above the protruding portion 127 as compared with the base plate 12 including the counterbore portion 126. This can reduce the influence of heat on the second sealing member 15.

### Seventh Embodiment

FIG. 13 is a schematic cross-sectional view illustrating a configuration example of the sample holder 1 according to the seventh embodiment. As illustrated in FIG. 13, the tubular member 13 may include a protruding portion 137 (corresponding to an example of a second protruding portion) that protrudes from the outer peripheral surface 133 of the tubular member 13 toward the outside of the tubular member 13, that is, toward the inner peripheral surface 125 of the through hole 123 of the base plate 12, at a middle portion of the base plate 12 in the thickness direction. The outer peripheral surface of the protruding portion 137 has a larger diameter than the outer peripheral surface 133 of the tubular member 13 and a smaller diameter than the inner peripheral surface 125 of the through hole 123 of the base plate 12.

In such a configuration, the lower side of the protruding portion 137 performs a function the same as or similar to that of the above-described counterbore portion 126 (see FIG. 11). That is, since the second sealing member 15 is located below the protruding portion 137, the position, the thickness, and the like of the second sealing member 15 can be easily controlled. Since the protruding portion 137 is located between the second sealing member 15 and the ceramic substrate 11, the radiant heat transmitted from the ceramic substrate 11 to the second sealing member 15 can be reduced by the protruding portion 137. Since the heat insulating space is formed above the protruding portion 137, the influence of heat on the second sealing member 15 can be reduced.

Note that the sample holder 1 may be configured to include the tubular member 13 (see FIG. 13) including the protruding portion 137 and the base plate 12 (see FIG. 11) including the counterbore portion 126. The sample holder 1 may be configured to include the tubular member 13 (see FIG. 13) including the protruding portion 137 and the base plate 12 (see FIG. 12) including the protruding portion 127.

### Eighth Embodiment

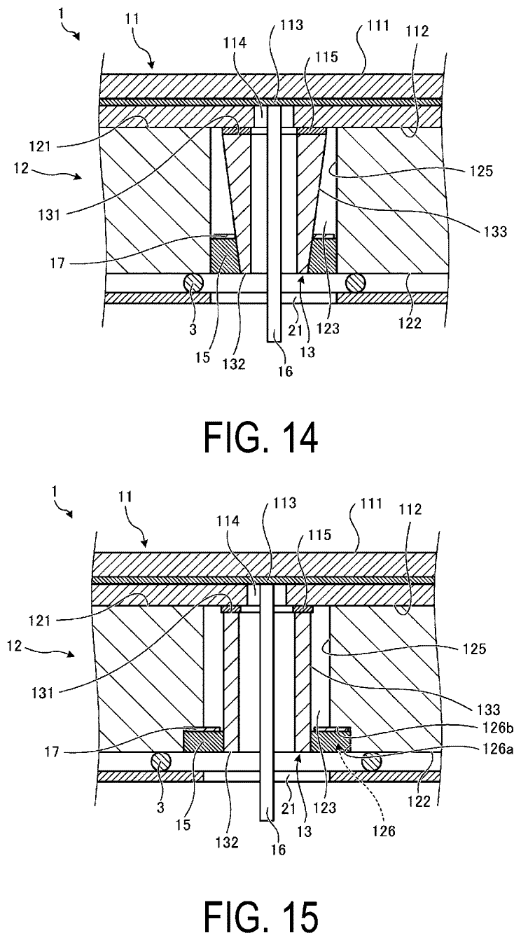

FIGS. 14 and 15 are schematic cross-sectional views each illustrating a configuration example of the sample holder 1 according to the eighth embodiment.

As illustrated in FIGS. 14 and 15, the sample holder 1 is located between the tubular member 13 and the base plate 12. Specifically, an annular member 17 that fits into the gap between the tubular member 13 and the base plate 12 may be provided. The annular member 17 may be made of, for example, a metal.

FIG. 14 illustrates an example in which the annular member 17 is located in the gap between the outer peripheral surface 133 of the tubular member 13 having a tapered shape and the inner peripheral surface 125 of the through hole 123. In this case, the annular member 17 is positioned in contact with the outer peripheral surface 133 of the tubular member 13. FIG. 15 illustrates an example in which the annular member 17 is located on the stepped surface 126b of the counterbore portion 126 provided in the base plate 12. In this case, the annular member 17 is positioned in contact with the stepped surface 126b. The inner diameter of the annular member 17 is larger than the outer peripheral surface 133 of the tubular member 13 and smaller than the inner peripheral surface 125 of the through hole 123. The outer diameter of the annular member 17 is larger than the inner peripheral surface 125 of the through hole 123 and smaller than the side surface 126a of the counterbore portion 126.

In the eighth embodiment, the second sealing member 15 is located in a region surrounded by the base plate 12, the tubular member 13, and the annular member 17.

By providing the annular member 17 in the gap between the inner peripheral surface 125 of the through hole 123 and the outer peripheral surface 133 of the tubular member 13 or in the stepped surface 126b of the counterbore portion 126, the position, the thickness, and the like of the second sealing member 15 can be easily controlled. Radiant heat transmitted from the ceramic substrate 11 to the second sealing member 15 can be reduced by the annular member 17.

### Ninth Embodiment

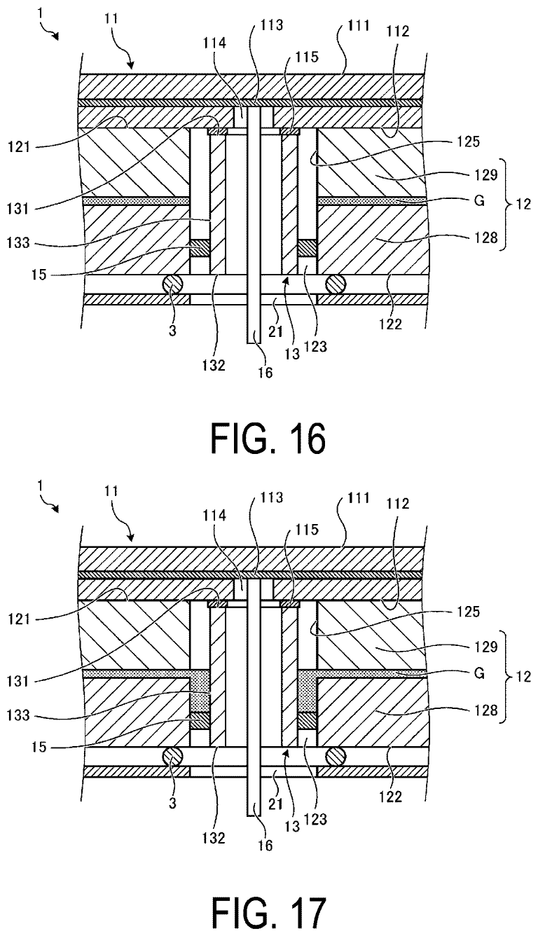

FIG. 16 is a schematic cross-sectional view illustrating a configuration example of the sample holder 1 according to the ninth embodiment. As illustrated in FIG. 16, the base plate 12 may include a cooling member 128, a heat-resistant member 129, and an adhesive G. The base plate 12 including the cooling member 128, the heat-resistant member 129, and the adhesive G has a disk shape having a diameter larger than that of the ceramic substrate 11 as a whole.

The cooling member 128 includes the fourth surface 122. The cooling member 128 may be, for example, a metal. As a metal material forming the cooling member 128, for example, aluminum matrix composite materials such as aluminum, stainless steel, titanium, and AlSiC can be used. The metal cooling member 128 can cool the ceramic substrate 11 heated by the heat generating resistor 113. The cooling member 128 may include an inner channel through which a cooling medium such as cooling water or cooling gas flows. The cooling member 128 may be used as a high-frequency electrode to which high-frequency power for plasma generation is applied.

The heat-resistant member 129 has the third surface 121 and is located between the ceramic substrate 11 and the cooling member 128. The heat-resistant member 129 is formed of a material having a relatively low coefficient of thermal conductivity. The heat-resistant member 129 has a coefficient of thermal conductivity lower than that of the base plate 12. As a material forming the heat-resistant member 129, for example, cordierite, glass, or the like can be used.

The adhesive G is located between the cooling member 128 and the heat-resistant member 129 and bonds the cooling member 128 and the heat-resistant member 129.

As described above, by providing the heat-resistant member 129 between the cooling member 128 and the ceramic substrate 11, heat conduction from the ceramic substrate 11 to the second sealing member 15 via the base plate 12 can be reduced.

Note that since the heat-resistant member 129 is interposed between the adhesive G and the ceramic substrate 11, the influence of the heat generated by the ceramic substrate 11 on the adhesive G is small as compared with the case where the adhesive is provided between the ceramic substrate and the base plate as in the related art. Therefore, the sample holder can withstand use under a high-temperature environment as compared with the conventional sample holder.

### Tenth Embodiment

FIG. 17 is a schematic cross-sectional view illustrating a configuration example of the sample holder 1 according to the tenth embodiment. As illustrated in FIG. 17, the adhesive G bonding the cooling member 128 and the heat-resistant member 129 may be located not only between the cooling member 128 and the heat-resistant member 129 but also between the cooling member 128 and the tubular member 13 in the through hole 123 to bond the cooling member 128 and the tubular member 13. The adhesive G located between the cooling member 128 and the tubular member 13 corresponds to an example of a “sealing member”.

Such a configuration can more reliably seal the gap between the base plate 12 and tubular member 13.

### Eleventh Embodiment

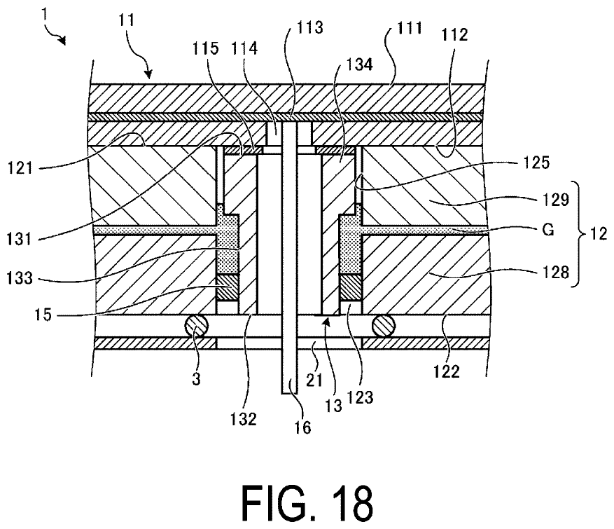

FIG. 18 is a schematic cross-sectional view illustrating a configuration example of the sample holder 1 according to the eleventh embodiment. As illustrated in FIG. 18, the adhesive G may also be located between the heat-resistant member 129 and the tubular member 13 in the through hole 123 to join the heat-resistant member 129 and the tubular member 13.

Such a configuration can further reliably seal the gap between the base plate 12 and tubular member 13.

### Twelfth Embodiment

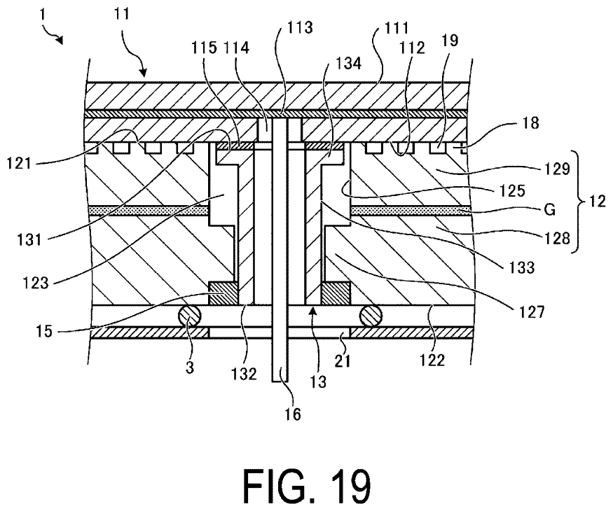

FIG. 19 is a schematic cross-sectional view illustrating a configuration example of the sample holder 1 according to the twelfth embodiment. As illustrated in FIG. 19, the heat-resistant member 129 may include a plurality of protruding portions 18 (corresponding to an example of third protruding portions) in contact with the ceramic substrate 11 and a space 19 located around each protruding portion 18 on the third surface 121 which is a surface on the ceramic substrate 11 side. The plurality of protruding portions 18 and the space 19 can be formed by, for example, blasting the third surface 121 of the heat-resistant member 129.

Since the heat-resistant member 129 includes the plurality of protruding portions 18 and the space 19, the contact surface area between the heat-resistant member 129 and the ceramic substrate 11 can be reduced. As a result, the ceramic substrate 11 easily slides with respect to the heat-resistant member 129. This can alleviate the stress generated by the difference in expansion and contraction between the heat-resistant member 129 and the ceramic substrate 11 due to the heat cycle.

The space 19 is located around each protruding portion 18 and between the ceramic substrate 11 and the heat-resistant member 129. The space 19 has a depth corresponding to the height of each protruding portion 18. A heat transfer gas such as helium may be introduced into the space 19. That is, the space 19 may be a channel for the heat transfer gas. By introducing the heat transfer gas into the space 19, the heat transfer gas can be fed to the second surface 112 of the ceramic substrate 11, thus improving the heat transfer property between the heat-resistant member 129 and the ceramic substrate 11 via the space 19.

The side surfaces of each protruding portion 18 may have a tapered shape in which the width decreases toward the ceramic substrate 11. In other words, each protruding portion 18 may be formed in a tapered shape in which the width decreases toward the apex portion of each protruding portion 18. By forming each protruding portion 18 in a tapered shape, the surface area of the end surface of each protruding portion 18 in contact with the ceramic substrate 11 can be reduced, and the contact surface area between the heat-resistant member 129 and the ceramic substrate 11 can be reduced. As a result, the ceramic substrate 11 can slide with respect to the heat-resistant member 129 more easily. This can further alleviate the stress generated by the difference in expansion and contraction between the heat-resistant member 129 and the ceramic substrate 11 due to the heat cycle.

A surface roughness Ra of the end surface of each protruding portion 18 in contact with the ceramic substrate 11 may be smaller than a surface roughness Ra of the bottom surface of the space 19. Accordingly, the end surface of each protruding portion 18 and the ceramic substrate 11 can be brought into uniform contact with each other in the in-plane direction, and heat transfer from the ceramic substrate 11 to the plurality of protruding portions 18 can be equalized. When the surface roughness Ra of the end surface of each protruding portion 18 in contact with the ceramic substrate 11 is small, the ceramic substrate 11 slides with respect to the heat-resistant member 129 more easily. This can further alleviate the stress generated by the difference in expansion and contraction between the heat-resistant member 129 and the ceramic substrate 11 due to the heat cycle. When the surface roughness Ra of the bottom surface of the space 19 is large, the surface area of the bottom surface of the space 19 can be increased. Thus, for example, when a heat transfer gas is introduced into the space 19, heat exchange between the heat transfer gas and the heat-resistant member 129 can be promoted.

As described above, the sample holder (as an example, the sample holder 1) according to the embodiments includes the ceramic substrate (as an example, the ceramic substrate 11), the base plate (as an example, the base plate 12), and the tubular member (as an example, the tubular member 13). The ceramic substrate includes a first surface (as an example, the first surface 111) which is a sample holding surface, and a second surface (as an example, the second surface 112) located opposite to the first surface. The base plate includes a third surface (as an example, the third surface 121) located on the second surface of the ceramic substrate and facing the second surface, a fourth surface (as an example, the fourth surface 122) located opposite to the third surface, and a through hole (as an example, the through hole 123) passing through the third surface and the fourth surface. The tubular member is located in the through hole and bonded to the second surface. The sample holder according to the embodiments includes a sealing member (as an example, the second sealing member 15 or the adhesive G) between an inner peripheral surface (for example, the inner peripheral surface 125) of the through hole and an outer peripheral surface (as an example, the outer peripheral surface 133) of the tubular member.

Therefore, according to the sample holder of the embodiments, the sealing property can be easily ensured under a high-temperature environment.

Embodiments have been described in order to fully and clearly disclose the technique according to the appended claims. However, the appended claims are not to be limited to the embodiments described above, and should be configured to embody all variations and alternative configurations that a person skilled in the art may make within the fundamental matter set forth in the present description.

1. A sample holder comprising:
a ceramic substrate;
a base plate; and
a tubular member,
wherein the ceramic substrate comprises a first surface being a sample holding surface and a second surface located opposite to the first surface,
the base plate comprises a third surface located on the second surface of the ceramic substrate and facing the second surface, a fourth surface located opposite to the third surface, and a through hole passing through the third surface and the fourth surface,
the tubular member is located in the through hole and is bonded to the second surface, and
a sealing member is provided between an inner peripheral surface of the through hole and an outer peripheral surface of the tubular member.

2. The sample holder according to claim 1, wherein the sealing member is located on a side of the fourth surface with respect to a center of the base plate in a thickness direction.

3. The sample holder according to claim 1, wherein a thermal expansion coefficient of the tubular member is smaller than a thermal expansion coefficient of the ceramic substrate.

4. The sample holder according to claim 1, wherein, in the tubular member, a surface area of a fifth surface being a bonding surface to the second surface is larger than a surface area of a sixth surface located opposite to the fifth surface.

5. The sample holder according to claim 4, wherein, in the tubular member, one end portion comprising the fifth surface has a flange shape.

6. The sample holder according to claim 5, wherein a corner portion or a nook portion of the one end portion is curved.

7. The sample holder according to claim 4, wherein the tubular member comprises a groove portion in the fifth surface.

8. The sample holder according to claim 1,
wherein the base plate comprises a counterbore portion recessed in a thickness direction of the base plate at an opening portion of the through hole on a side of the fourth surface, and
the sealing member is located in the counterbore portion.

9. The sample holder according to claim 1, wherein the base plate comprises a first protruding portion protruding toward an inner side of the through hole at a middle portion of the through hole.

10. The sample holder according to claim 1, wherein the tubular member comprises a second protruding portion protruding toward the base plate at a middle portion of the base plate in a thickness direction.

11. The sample holder according to claim 1, further comprising an annular member located between the tubular member and the base plate,
wherein the sealing member is located in a region surrounded by the base plate, the tubular member, and the annular member.

12. The sample holder according to claim 1,
wherein the base plate comprises:
a heat-resistant member;
a cooling member; and
an adhesive bonding the heat-resistant member and the cooling member,
the heat-resistant member comprises the third surface, and
the cooling member comprises the fourth surface.

13. The sample holder according to claim 12, wherein the adhesive is further located between the cooling member and the tubular member in the through hole and bonds the cooling member and the tubular member.

14. The sample holder according to claim 12, wherein the adhesive is further located between the heat-resistant member and the tubular member in the through hole and bonds the heat-resistant member and the tubular member.

15. The sample holder according to claim 12, wherein the heat-resistant member comprises a plurality of third protruding portions in contact with the ceramic substrate and a space located around the third protruding portions.

16. The sample holder according to claim 15, wherein side surfaces of the third protruding portions have a tapered shape having a width decreasing toward the ceramic substrate.

17. The sample holder according to claim 15, wherein a surface roughness of end surfaces of the third protruding portions in contact with the ceramic substrate is smaller than a roughness of a bottom surface of the space.
